(19) United States
(12) Patent Application Publication
(10) Pub. No.: US 2026/0333950 A1
(43) Pub. Date: Oct. 22, 2026

(54) LIGHT-EMITTING CHIP AND METHOD FOR MANUFACTURING THE SAME, DISPLAY SUBSTRATE AND METHOD FOR MANUFACTURING THE SAME, AND DISPLAY DEVICE

(71) Applicants: Beijing BOE Technology Development Co., Ltd., Beijing (CN); BOE Technology Group Co., Ltd., Beijing (CN)

(72) Inventors: Mingxing WANG, Beijing (CN); Qian SUN, Beijing (CN); Wei LI, Beijing (CN); Huajie YAN, Beijing (CN); Zhiqiang JIAO, Beijing (CN); Ying ZHOU, Beijing (CN); Tianhang GAO, Beijing (CN)

(21) Appl. No.: 18/852,271

(22) PCT Filed: Nov. 30, 2023
(86) PCT No.: PCT/CN2023/135412

§ 371 Date: Sep. 27, 2024

(51) Int. Cl. H10H 20/812; H10H 20/01; H10H 20/851; H10H 29/24

(52) U.S. Cl. CPC H10H 20/812; H10H 20/0137; H10H 20/8514; H10H 29/24

(57) ABSTRACT

A light-emitting chip is provided including: an LED light-emitting unit configured to emit light of a first wavelength; and a light conversion unit on a light output side of the LED light-emitting unit, is configured to convert the light of the first wavelength into light of a second wavelength, and colors of the light of the first wavelength and the light of the second wavelength are different. The light conversion unit includes: a first bonding layer on the light output side of the LED light-emitting unit; a first quantum well layer on a side of the first bonding layer away from the LED light-emitting unit; and a first semiconductor layer on a side of the first quantum well layer away from the LED light-emitting unit. The first quantum well layer is configured to emit the light of the second wavelength under an excitation of the light of the first wavelength.

### CROSS-REFERENCE TO RELATED APPLICATION(S)

This application is a Section 371 National Stage Application of International Application No. PCT/CN2023/135412, filed Nov. 30, 2023, entitled “LIGHT-EMITTING CHIP AND METHOD FOR MANUFACTURING THE SAME, DISPLAY SUBSTRATE AND METHOD FOR MANUFACTURING THE SAME, AND DISPLAY DEVICE”, which is incorporated herein by reference in its entirety.

### TECHNICAL FIELD

The present disclosure relates to a field of display technology, in particular to a light-emitting chip and a method for manufacturing the same, a display substrate and a method for manufacturing the same, and a display device.

### BACKGROUND

With the development of display technology, high requirements are put forward for the luminance and resolution of display products. Mini light-emitting diode (Mini-LED) light-emitting chips and micro light-emitting diode (Micro-LED) light-emitting chips are widely used in the field of high-resolution display.

However, as the size of a light-emitting chip decreases, the efficiency of the light-emitting chip decreases, especially the efficiency of a red LED light-emitting chip and the efficiency of a green LED light-emitting chip decrease significantly as the size of the chip decreases, resulting in a great impact on the performance of display products. How to manufacture high-efficiency and multi-color light-emitting chips in the miniaturization of light-emitting chips is one of the important research topics for R&D personnel.

### SUMMARY

In a first aspect, a light-emitting chip is provided, including: an LED light-emitting unit configured to emit light of a first wavelength; and a light conversion unit on a light output side of the LED light-emitting unit, configured to convert the light of the first wavelength into light of a second wavelength, a color of the light of the first wavelength being different from a color of the light of the second wavelength. The light conversion unit includes: a first bonding layer on the light output side of the LED light-emitting unit; a first quantum well layer on a side of the first bonding layer away from the LED light-emitting unit; and a first semiconductor layer on a side of the first quantum well layer away from the LED light-emitting unit, where the first quantum well layer is configured to emit the light of the second wavelength under an excitation of the light of the first wavelength.

According to some exemplary embodiments, the LED light-emitting unit includes: a first buffer layer on a side of the first bonding layer away from the first quantum well layer; a second semiconductor layer on a side of the first buffer layer away from the first quantum well layer; a second quantum well layer on a side of the second semiconductor layer away from the first quantum well layer; a third semiconductor layer on a side of the second quantum well layer away from the first quantum well layer; and a first electrode on a side of the third semiconductor layer away from the first quantum well layer.

According to some exemplary embodiments, the second semiconductor layer includes a second electrode connection portion not covered by the second quantum well layer; and the LED light-emitting unit further includes: a second electrode on a side of the second electrode connection portion away from the first quantum well layer; and a first insulation layer on a side of each of the first electrode and the second electrode away from the first quantum well layer. The first insulation layer includes a first via hole exposing at least a part of the first electrode and a second via hole exposing at least a part of the second electrode; and the LED light-emitting unit further includes: a first extraction electrode; and a second extraction electrode, where the first extraction electrode is electrically connected to the first electrode through the first via hole; and the second extraction electrode is electrically connected to the second electrode through the second via hole.

According to some exemplary embodiments, an orthographic projection of the second quantum well layer on the first bonding layer falls within an orthographic projection of the first quantum well layer on the first bonding layer.

According to some exemplary embodiments, a thickness of the first semiconductor layer is greater than or equal to 500 nm and less than or equal to 5 μm; and/or, a number of quantum well pairs in the first quantum well layer is greater than or equal to 10; and/or, a thickness of the first bonding layer is greater than or equal to 10 nm and less than or equal to 5 μm.

According to some exemplary embodiments, a material of the first semiconductor layer includes AlGaInP; and/or, a material of the first quantum well layer includes an AlGaInP quantum well; and/or, a material of the first bonding layer includes at least one of SiO₂, benzocyclobutene, or SU8 negative photoresist.

According to some exemplary embodiments, the light of the first wavelength emitted by the LED light-emitting unit includes light with a wavelength greater than or equal to 200 nm and less than or equal to 495 nm; and/or, the light of the second wavelength includes light with a wavelength greater than or equal to 620 nm and less than or equal to 760 nm.

According to some exemplary embodiments, the light-emitting chip further includes a reflective layer covering at least part of sidewalls of the LED light-emitting unit. The reflective layer includes a first reflective sub-layer, a second reflective sub-layer, and a third reflective sub-layer; the sidewalls of the LED light-emitting unit include a first sidewall, a second sidewall, and a third sidewall; the first reflective sub-layer covers at least a part of the first sidewall; the second reflective sub-layer covers at least a part of the second sidewall; the third reflective sub-layer covers at least a part of the third sidewall. The first sidewall includes a sidewall among the sidewalls of the LED light-emitting unit on a side close to the first extraction electrode and away from the second extraction electrode; the second sidewall includes a sidewall among the sidewalls of the LED light-emitting unit between the first extraction electrode and the second extraction electrode; and the third sidewall includes a sidewall among the sidewalls of the LED light-emitting unit on a side close to the second extraction electrode and away from the first extraction electrode.

According to some exemplary embodiments, the reflective layer further includes a first passivation layer, a first metal reflective layer, and a second passivation layer.

According to some exemplary embodiments, the light-emitting chip further includes a first inorganic reflective layer between the first semiconductor layer and the first quantum well layer, where the first inorganic reflective layer includes a stack including a GaAs layer and an AlAs layer.

According to some exemplary embodiments, a material of the first electrode includes ITO; and/or, a material of the second electrode includes Ti or Cr; and/or, the first extraction electrode and the second extraction electrode are arranged in a same layer, and each of the first extraction electrode and the second extraction electrode includes one of Ti, Al, Au, Sn, Ni or Pt, or an alloy of more than one selected from Ti, Al, Au, Sn, Ni or Pt, or a stack of more than one selected from Ti, Al, Au, Sn, Ni or Pt.

In a second aspect, a Mini-LED light-emitting chip is provided, including: a second substrate; a second bonding layer on the second substrate; and a light-emitting chip on a side of the second bonding layer away from the second substrate, where the light-emitting chip includes any one of the above-mentioned light-emitting chips, and the second substrate is arranged on a light output side of the light-emitting chip.

In a third aspect, a light-emitting chip array is provided, including: a first substrate; a third bonding layer on the first substrate; and a plurality of light-emitting chips arranged in an array on a side of the third bonding layer away from the first substrate, where the light-emitting chips include any one of the above-mentioned light-emitting chips.

In a fourth aspect, a method for manufacturing a light-emitting chip is provided, including: depositing a first buffer material layer, a second semiconductor material layer, a second quantum well material layer, and a third semiconductor material layer sequentially on a first wafer, so as to form an LED epitaxial layer; forming a first electrode material layer on a side of the LED epitaxial layer away from the first wafer; patterning the LED epitaxial layer and the first electrode material layer, so as to form a mesa not covered by the second quantum well material layer on the second semiconductor material layer; forming a second electrode material layer on a side of the mesa of the second semiconductor material layer not covered by the second quantum well material layer away from the first wafer; forming a first insulation material layer on a side of each of the first electrode material layer and the second electrode material layer away from the first wafer, and patterning the first insulation material layer, so as to form a first via hole exposing a part of the first electrode material layer and a second via hole exposing a part of the second electrode material layer; forming a metal conductive material layer on a side of the first insulation material layer away from the first wafer, and patterning the metal conductive material layer to form a first extraction electrode electrically connected to the first electrode material layer through the first via hole and a second extraction electrode electrically connected to the second electrode material layer through the second via hole, so as to form an LED light-emitting unit on the first wafer; patterning the LED light-emitting unit to form a plurality of LED light-emitting units on the first wafer; forming a third bonding material layer on a side of the metal conductive material layer away from the first wafer; forming a first substrate on a side of the third bonding material layer away from the first wafer; removing the first wafer, so as to form the plurality of LED light-emitting units on the first substrate; depositing a second buffer material layer, a first semiconductor material layer and a first quantum well material layer sequentially on a second wafer, so as to form a light conversion unit on the second wafer; forming a first bonding material layer between the first buffer material layer and the first quantum well material layer, so as to bond the plurality of LED light-emitting units and the light conversion unit; and removing the second wafer and the second buffer material layer, so as to form the light-emitting chip on the first substrate.

According to some exemplary embodiments, the patterning the LED light-emitting unit to form a plurality of LED light-emitting units on the first wafer includes: patterning the LED light-emitting unit to form a plurality of Mini-LED light-emitting units on the first wafer; and the method further includes: forming a second bonding material layer on a side of the first semiconductor layer away from the first substrate; forming a second substrate on a side of the second bonding material layer away from the first substrate; removing the first substrate and the third bonding material layer; and patterning each of the second substrate, the second bonding material layer, the first semiconductor material layer, the first quantum well material layer, and the first bonding material layer, so as to form the plurality of individual Mini-LED light-emitting chips.

According to some exemplary embodiments, the patterning the LED light-emitting unit to form a plurality of LED light-emitting units on the first wafer includes: performing the patterning process on the LED light-emitting unit to form a plurality of Micro-LED light-emitting units on the first wafer; the method further includes: patterning each of the first semiconductor material layer, the first quantum well material layer, and the first bonding material layer, so as to form the plurality of Micro-LED light-emitting chip arranged in an array on the first substrate.

In a fifth aspect, a display substrate is provided, including: a base substrate; and a plurality of pixel units on the base substrate. At least one of the plurality of pixel units includes a first sub-pixel, a second sub-pixel, and a third sub-pixel, each of the first sub-pixel, the second sub-pixel and the third sub-pixel includes an LED light-emitting unit and a light guiding layer, and the LED light-emitting unit is configured to emit light of a first wavelength. The light guiding layers of the sub-pixels include a second light conversion layer on a light output side of the LED light-emitting unit of the second sub-pixel, and the second light conversion layer is configured to convert the light of the first wavelength into a light of a second wavelength, where an orthographic projection of the LED light-emitting unit of the second sub-pixel on the base substrate falls with an orthographic projection of the second light conversion layer on the base substrate. The light guiding layers of the sub-pixels further includes a third light conversion layer on a light output side of the LED light-emitting unit of the third sub-pixel, and the third light conversion layer is configured to convert the light of the first wavelength into light of a third wavelength, where an orthographic projection of the LED light-emitting unit of the third sub-pixel on the base substrate falls within an orthographic projection of the third light conversion layer on the base substrate, and colors of the light with the first wavelength, the light with the second wavelength and the light with the third wavelength are different from each other.

According to some exemplary embodiments, the second light conversion layer includes a red light quantum dot material; and/or, the third light conversion layer includes a green light quantum dot material.

According to some exemplary embodiments, the light guiding layers of the sub-pixels further includes a first light guiding layer on a light output side of the LED light-emitting unit of the first sub-pixel, where an orthographic projection of the LED light-emitting unit of the first sub-pixel on the base substrate falls within an orthographic projection of the first light guiding layer on the base substrate; and a material of the first light guiding layer includes scattering particles.

According to some exemplary embodiments, the light guiding layers of the sub-pixels further includes a first light conversion layer on a light output side of the LED light-emitting unit of the first sub-pixel, the first light conversion layer is configured to convert the light of the first wavelength into light of a fourth wavelength, and a color of the light of the first wavelength is different from a color of the light of the fourth wavelength, where the first light conversion layer includes a blue light quantum dot material; and an orthographic projection of the LED light-emitting unit of the first sub-pixel on the base substrate falls within an orthographic projection of the first light conversion layer on the base substrate.

According to some exemplary embodiments, the display substrate further includes a second dielectric layer on a side of the light guiding layers away from the base substrate, where the second dielectric layer includes a main body portion and an isolation portion, and the isolation portion is in a gap between light guiding layers of adjacent sub-pixels; an orthographic projection of the second dielectric layer on the base substrate does not overlap with the orthographic projection of the LED light-emitting unit of the first sub-pixel on the base substrate; and an orthographic projection of each of the LED light-emitting unit of the second sub-pixel and the LED light-emitting unit of the third sub-pixel on the base substrate falls within an orthographic projection of the main body portion of the second dielectric layer on the base substrate.

According to some exemplary embodiments, the display substrate further includes a second dielectric layer on a side of the light guiding layer away from the base substrate, where the second dielectric layer includes a main body portion and an isolation portion, and the isolation portion is in a gap between light guiding layers of adjacent sub-pixels; and an orthographic projection of each of the LED light-emitting unit of the first sub-pixel, the LED light-emitting unit of the second sub-pixel and the LED light-emitting unit of the third sub-pixel on the base substrate falls within an orthographic projection of the main body portion of the second dielectric layer on the base substrate.

According to some exemplary embodiments, the second dielectric layer includes a stacked structure of a SiO₂ layer and a TiO₂ layer; or the second dielectric layer includes a stacked structure of a SiO₂ layer and a NbO₂ layer; and/or, the second dielectric layer has a third thickness in a direction perpendicular to the base substrate, and the third thickness is less than or equal to 5 μm.

According to some exemplary embodiments, the display substrate further includes a first dielectric layer between the LED light-emitting units and the light guiding layers. The first dielectric layer includes a stack of a SiO₂ layer and a TiO₂ layer; or the first dielectric layer includes a stacked structure of a SiO₂ layer and a NbO₂ layer; and/or, the first dielectric layer has a fourth thickness in a direction perpendicular to the base substrate, and the fourth thickness is less than or equal to 5 μm.

According to some exemplary embodiments, the display substrate further includes a black adhesive layer between adjacent sub-pixels, the black adhesive layer is located on a side of a second dielectric layer away from the base substrate and is configured to reflect at least part of light, which is emitted from one of the adjacent sub-pixels towards the other one of the adjacent sub-pixels.

In a sixth aspect, a display device is provided, including any one of the above-mentioned display substrates.

In a seventh aspect, a method for manufacturing a display substrate is provided, including: forming a plurality of LED light-emitting units on a base substrate; forming a first dielectric material layer on a side of the plurality of LED light-emitting units away from the base substrate; depositing layers of different light guiding materials on a side of the first dielectric material layer away from the base substrate through a plurality of steps respectively, and patterning the layers of different light guiding materials, so as to form light guiding material layers corresponding to different LED light-emitting units respectively; forming a second dielectric layer on a side of the light guiding material layers away from the base substrate, and patterning the second dielectric layer; and forming a black adhesive layer on a side of the second dielectric layer away from the base substrate and patterning the black adhesive layer, so as to form the display substrate.

### BRIEF DESCRIPTION OF THE DRAWINGS

The above, and other objectives, features and advantages of the present disclosure will become clearer through the following description of embodiments of the present disclosure with reference to the accompanying drawings, in which:

FIG. 1 is a schematic diagram of a structure of a light-emitting chip according to some exemplary embodiments of the present disclosure;

FIG. 2 is a diagram showing a relationship between projections of a first quantum well layer and a second quantum well layer in a light-emitting chip according to some exemplary embodiments of the present disclosure;

FIG. 3A is a schematic diagram of a structure of a light-emitting chip according to some exemplary embodiments of the present disclosure; FIG. 3B is a schematic diagram of a structure of a reflective layer in a light-emitting chip according to some exemplary embodiments of the present disclosure;

FIG. 4 is a schematic diagram of a structure of a light-emitting chip according to some exemplary embodiments of the present disclosure;

FIG. 5 is a schematic diagram of a structure of a Mini-LED light-emitting chip according to some exemplary embodiments of the present disclosure;

FIG. 6 is a schematic diagram of a structure of a light-emitting chip array according to some exemplary embodiments of the present disclosure;

FIG. 7 is a flowchart of a method for manufacturing a light-emitting chip according to some exemplary embodiments of the present disclosure; FIG. 8 to FIG. 20 are respectively schematic diagrams showing a local structure of a light-emitting chip at different stages of the manufacturing process in FIG. 7;

FIG. 21 is a flowchart of a method for manufacturing a Mini-LED light-emitting chip according to some exemplary embodiments of the present disclosure; FIG. 22 to FIG. 25 are respectively schematic diagrams showing a local structure of the Mini-LED light-emitting chip at different stages of the manufacturing process in FIG. 21;

FIG. 26 is a schematic diagram of a structure of a light-emitting chip array according to some exemplary embodiments of the present disclosure;

FIG. 27 is a schematic plan view of a display substrate according to some exemplary embodiments of the present disclosure; FIG. 28 is a schematic diagram of a local cross-section of the display substrate in FIG. 27 taken along line AA′ according to some exemplary embodiments of the present disclosure;

FIG. 29 is a schematic diagram of a local cross-section of the display substrate in FIG. 27 taken along line AA′ according to some other exemplary embodiments of the present disclosure;

FIG. 30 is a schematic diagram of a local cross-section of the display substrate in FIG. 27 taken along line AA′ according to some other exemplary embodiments of the present disclosure; FIG. 31 is a schematic diagram of a local cross-section of the display substrate in FIG. 27 taken along line AA′ according to some other exemplary embodiments of the present disclosure;

FIG. 32 is a schematic diagram of a structure of a display device according to some exemplary embodiments of the present disclosure; and

FIG. 33 is a flowchart of a method for manufacturing a display substrate according to some exemplary embodiments of the present disclosure; FIG. 34 to FIG. 38 are respectively schematic diagrams showing a local structure of the display substrate at different stages of the manufacturing process in FIG. 33.

It should be noted that, for the sake of clarity, dimensions of layers, structures, or regions may be enlarged or reduced in the accompanying drawings used to describe the embodiments of the present disclosure, that is, these drawings are not drawn to the actual scale.

### DETAILED DESCRIPTION

In order to make the objectives, technical solution and advantages of embodiments of the present disclosure clearer, the technical solution(s) of the embodiments of the present disclosure will be clearly and completely described below in conjunction with the drawings of the embodiments of the present disclosure. Obviously, the described embodiments are only some of the embodiments of the present disclosure, rather than all the embodiments. Based on the described embodiments of the present disclosure, all other embodiments obtained by those ordinary skilled in the art without inventive labor are within the scope of protection of the present disclosure.

It should be noted that, for sake of clarity and/or description, dimensions and relative dimensions of elements may be enlarged in the drawings. Thus, the dimensions and relative dimensions of the respective elements are not necessarily limited to the dimensions and relative dimensions shown in the drawings. In the specification and drawings, the same or similar reference numerals indicate the same or similar components.

Unless otherwise defined, the technical or scientific terms used in the present disclosure shall have the usual meanings understood by those skilled in the art. The terms “first”, “second”, and similar words used in the present disclosure do not indicate any order, quantity, or importance, but are only used to distinguish different components. Words such as “including”, “comprising” or the like refer to that the elements or objects preceding the word include those listed following the word and their equivalents, but do not exclude other elements or objects.

In the present disclosure, unless otherwise specified, directional terms such as “up”, “down”, “left”, “right”, “inside”, “outside”, etc. are used to indicate the orientation or positional relationship based on the drawings, only for the convenience of describing the present disclosure, and not to indicate or imply that the device, element, or component referred to must have a specific orientation, or must be constructed or operated in a specific orientation. It should be understood that when the absolute position of the described object changes, the relative positional relationship they represent may also change accordingly. Therefore, these directional terms cannot be understood as limitations to the present disclosure.

It should be noted that, in the present disclosure, the expression “same layer” refers to a layer structure formed by: forming a film layer used for forming a specific pattern through the same film forming process, and then patterning the film layer through a single patterning process with the same mask. Depending on the specific pattern, the patterning process may include a plurality of exposure, development or etching processes, and the specific pattern in the formed layer structure may be continuous or discontinuous. That is, a plurality of elements, components, structures and/or parts located in the “same layer” are composed of the same material and are formed through the same patterning process. Generally, the plurality of elements, components, structures and/or parts located in the “same layer” have substantially the same thickness.

Those skilled in the art should understand that, in the present disclosure, unless otherwise specified, the expression “height” or “thickness” refers to a dimension of a surface of each film layer arranged perpendicular to the display substrate. That is, a dimension along the light output direction of the display substrate, or a dimension along the normal direction of the display device.

In the present disclosure, the directional expressions “first direction” and “second direction” are used to describe different directions along the pixel unit, for example, longitudinal and transverse directions of the pixel unit, or row and column directions in which the sub-pixels are arranged. It should be understood that such representations are merely exemplary descriptions and are not limitations to the present disclosure.

In the resent disclosure, the inorganic light-emitting diode refers to a light-emitting element made of an inorganic material, and LED represents an inorganic light-emitting element different from OLED. Specifically, the inorganic light-emitting element may include mini light-emitting diode (Mini-LED) and micro light-emitting diode (Micro-LED). Here, a micro light-emitting diode (i.e. Micro-LED) refers to an ultra-small light-emitting diode with a die size less than 100 microns, and a mini light-emitting diode (i.e. Mini-LED) refers to a small light-emitting diode with a die size between that of a Micro-LED and that of a traditional LED. For example, the die size of the Mini-LED may be between 50 microns to 40 microns.

LEDs may be used to manufacture mini-LED and Micro-LED display screens due to their characteristics such as a high refresh rate, a high luminance, an active light-emitting mode, and capability of being miniaturized. However, as the size of the light-emitting chip decreases, the efficiency of the light-emitting chip decreases, especially the efficiency of a red LED light-emitting chip and that of a green LED light-emitting chip decrease significantly as the size of the chip decreases, causing a great impact on the performance of display products. The existing red light LED light-emitting chips are usually manufactured using AlGaInP materials. Since AlGaInP system materials have an electron drift rate higher than that of GaN system materials, the efficiency of red light LED light-emitting chips decreases significantly as the size of the chip decreases, causing a great impact on the performance of display products. How to manufacture high-efficiency light-emitting chips with a plurality of colors during the miniaturization of light-emitting chips is an urgent problem for R&D personnel to solve.

In the embodiments of the present disclosure, a light-emitting chip is provided, including: an LED light-emitting unit configured to emit light of a first wavelength; and a light conversion unit on a light output side of the LED light-emitting unit, the light conversion unit being configured to convert the light of the first wavelength into light of a second wavelength, where a color of the light of the first wavelength is different from a color of the light of the second wavelength. The light conversion unit includes: a first bonding layer on the light output side of the LED light-emitting unit; a first quantum well layer on a side of the first bonding layer away from the LED light-emitting unit; and a first semiconductor layer on a side of the first quantum well layer away from the LED light-emitting unit. The first quantum well layer is configured to emit the light of the second wavelength under an excitation of the light of the first wavelength.

By combining a small-sized blue LED light-emitting diode or a small-sized ultraviolet LED light-emitting diode with an inorganic quantum well structure, the small-sized blue LED light-emitting diode or the small-sized ultraviolet LED light-emitting diode, which has a high efficiency, is used to emit the light of the first wavelength, and then the inorganic quantum well structure is excited by the light of the first wavelength to emit the light of the second wavelength which may include red light, so as to form a small-sized red LED light-emitting chip, so that the efficiency and stability of the small-sized red LED light-emitting chip may be improved effectively.

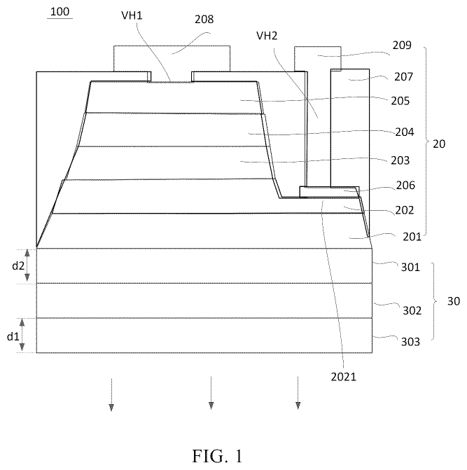

FIG. 1 is a schematic diagram of a structure of a light-emitting chip according to some exemplary embodiments of the present disclosure.

Referring to FIG. 1, a light-emitting chip 100 includes: an LED light-emitting unit 20 configured to emit light of a first wavelength λ1; and a light conversion unit 30 on a light output side of the LED light-emitting unit 20. The light conversion unit 30 is configured to convert the light of the first wavelength λ1 into light of a second wavelength λ2, and a color of the light of the first wavelength λ1 is different from a color of the light of the second wavelength λ2. The light conversion unit 30 includes: a first bonding layer 301 on the light output side of the LED light-emitting unit 20; a first quantum well layer 302 on a side of the first bonding layer 301 away from the LED light-emitting unit 20; and a first semiconductor layer 303 on a side of the first quantum well layer 302 away from the LED light-emitting unit 20. The first quantum well layer 302 is configured to emit the light of the second wavelength λ2 under an excitation of the light of the first wavelength λ1.

Exemplarily, in some embodiments of the present disclosure, the light of the first wavelength λ1 emitted by the LED light-emitting unit 20 includes light with a wavelength greater than or equal to 200 nm and less than or equal to 495 nm. For example, the LED light-emitting unit 20 may include a LED light-emitting unit that emits blue light, where light of the first wavelength λ1 emitted by the LED light-emitting unit that emits blue light includes light with a wavelength greater than or equal to 395 nm and less than or equal to 495 nm. Alternatively, the LED light-emitting unit 20 may include an LED light-emitting unit that emits ultraviolet light, where light of the first wavelength λ1 emitted by the LED light-emitting unit that emits ultraviolet light includes light with a wavelength greater than or equal to 200 nm and less than or equal to 400 nm. By using the light emitted by the blue light LED light-emitting unit or ultraviolet light LED light-emitting unit which has a small size and high efficiency to excite the first quantum well layer structure, the light of the second wavelength may be obtained. For example, the light of the second wavelength includes red light with a wavelength greater than or equal to 620 nm and less than or equal to 760 nm, so as to obtain a high-efficiency and small-sized red light LED light-emitting chip.

Exemplarily, in some embodiments of the present disclosure, with continued reference to FIG. 1, the LED light-emitting unit 20 includes: a first buffer layer 201 on a side of the first bonding layer 301 away from the first quantum well layer 302; a second semiconductor layer 202 on a side of the first buffer layer 201 away from the first quantum well layer 302; a second quantum well layer 203 on a side of the second semiconductor layer 202 away from the first quantum well layer 302; a third semiconductor layer 204 on a side of the second quantum well layer 203 away from the first quantum well layer 302; and a first electrode 205 on a side of the third semiconductor layer 204 away from the first quantum well layer 302.

Exemplarily, in some embodiments of the present disclosure, with continued reference to FIG. 1, the second semiconductor layer 202 may include a second electrode connection portion 2021 not covered by the second quantum well layer 203.

The LED light-emitting unit 20 further includes: a second electrode 206 on a side of the second electrode connection portion 2021 away from the first quantum well layer 302; and a first insulation layer 207 on a side of each of the first electrode 205 and the second electrode 206 away from the first quantum well layer 302. The first insulation layer 207 includes a first via hole VH1 exposing at least a part of the first electrode 205 and a second via hole VH2 exposing at least a part of the second electrode 206.

The LED light-emitting unit 20 further includes a first extraction electrode 208 and a second extraction electrode 209. The first extraction electrode 208 is electrically connected to the first electrode 205 through the first via hole VH1. The second extraction electrode 209 is electrically connected to the second electrode 206 through the second via hole VH2.

By designing the first extraction electrode and the second extraction electrode, where the first extraction electrode and the second extraction electrode may be arranged in the same layer, it is possible to facilitate the connection between the LED light-emitting unit and an external part, such as the bonding between the LED light-emitting unit and the light conversion unit 30.

Exemplarily, in some embodiments of the present disclosure, a material of the first electrode 205 may include ITO. A thickness of ITO may be in a range of 1 nm to 5000 nm. Preferably, the thickness of ITO is in a range of 50 nm to 300 nm. By optimizing the material kind and the thickness of the first electrode, the first electrode may have good transmittance and conductivity. The first electrode material may also be annealed, which may improve the transmittance of the first electrode and enhance the ohmic contact property between the first electrode and the first extraction electrode.

Exemplarily, a material of the second electrode 206 may include Ti or Cr; and/or, a material of each of the first extraction electrode 208 and the second extraction electrode 209 may include one of Ti, Al, Au, Sn, Ni or Pt, or an alloy of more than one selected from Ti, Al, Au, Sn, Ni or P, or a stack of more than one selected from Ti, Al, Au, Sn, Ni or P. For example, the material of the second electrode 206 may be Ti, and the layer of metal or alloy of the second extraction electrode 209 in contact with the second electrode 206 also contains Ti, so that the ohmic contact property between the second electrode 206 and the second extraction electrode 209 may be improved.

Exemplarily, the material of the second electrode 206 may also be Cr, and the layer of metal or alloy of the second extraction electrode 209 in contact with the second electrode 206 also contains Cr, so that the ohmic contact property between the second electrode 206 and the second extraction electrode 209 may be improved.

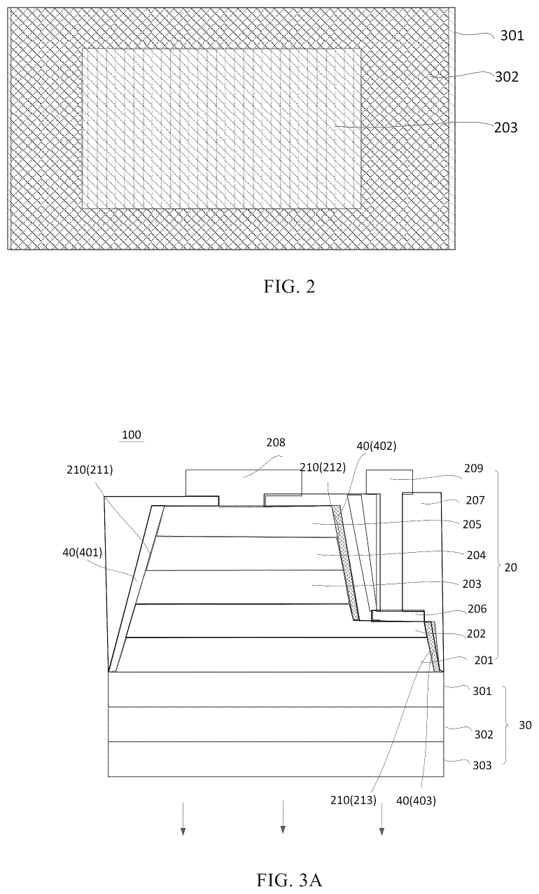

FIG. 2 is a diagram showing a relationship between projections of a first quantum well layer and a second quantum well layer in a light-emitting chip according to some exemplary embodiments of the present disclosure.

Exemplarily, in some embodiments of the present disclosure, referring to FIG. 2, an orthographic projection of the second quantum well layer 203 on the first bonding layer 301 falls within an orthographic projection of the first quantum well layer 302 on the first bonding layer 301. By designing the size of the first quantum well layer to be greater than the size of the LED light-emitting unit 20, a side light leakage may be effectively reduced and an efficiency of converting the light of the first wavelength into the light of the second wavelength may be improved, thereby enhancing the overall light efficiency of the light-emitting chip.

Exemplarily, in some embodiments of the present disclosure, a material of the first semiconductor layer 303 may include AlGaInP; and/or, a material of the first quantum well layer 302 may include an AlGaInP quantum well. For example, the first quantum well layer 302 may be epitaxially grown on the first semiconductor layer 303. The first quantum well layer may include a well and a barrier which include AlGaInP/AlGaInP.

Exemplarily, a material of the first bonding layer 301 may include at least one of SiO₂, benzocyclobutene, or a SU8 negative photoresist. The first bonding layer is used to bond the light conversion unit 30 with the LED light-emitting unit 20. The material of the first bonding layer may include a permanent bonding adhesive, such as benzocyclobutene, SU8 negative photoresist or other adhesive materials. Or, the material of the first bonding layer may include an inorganic dielectric material, such as SiO₂.

Exemplarily, in some embodiments of the present disclosure, with continued reference to FIG. 1, the first semiconductor layer 303 has a first thickness d1 in a direction perpendicular to the light output surface, and the first thickness d1 is greater than or equal to 500 nm and less than or equal to 5 μm. Lattice mismatch between the first semiconductor layer 303 and the first quantum well layer 302 may be reduced by adjusting the thickness of the first semiconductor layer.

Exemplarily, the first bonding layer 301 has a second thickness d2 in the direction perpendicular to the light output surface, and second thickness d2 is greater than or equal to 10 nm and less than or equal to 5 μm. Preferably, the second thickness d2 is in a range greater than or equal to 10 nm and less than or equal to 2.5 μm. By adjusting the thickness of the first bonding layer, a bonding strength of the bonding layer may be ensured, and the side light leakage may be reduced. For example, in some embodiments, the material of the first bonding layer is benzocyclobutene. Benzocyclobutene is spin-coated on the first quantum well layer to a thickness of 2.5 μm, and then is placed under vacuum conditions of 250 °C, 5000 N pressure and 1 mBar for 1 hour, so that the bonding between the LED light-emitting unit 20 and the light conversion unit 30 may be achieved. By adjusting the material, the thickness, or process parameters of the first bonding layer, blue light transmittance of the first bonding layer may be improved. For example, the blue light transmittance of the first bonding layer may be greater than or equal to 95%.

Exemplarily, the number of quantum well pairs in the first quantum well layer 302 is greater than or equal to 10. Preferably, the number of quantum well pairs in the first quantum well layer 302 is in a range of 20 pairs to 40 pairs. By optimizing the number of quantum well pairs in the first quantum well layer, the light conversion efficiency of the light conversion unit may be further improved, thereby enhancing the light efficiency of the light-emitting chip.

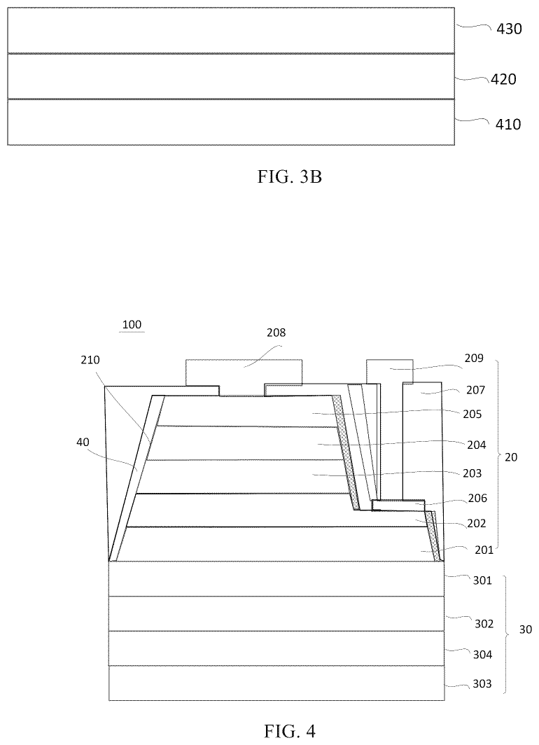

FIG. 3A is a schematic diagram of a structure of a light-emitting chip according to some exemplary embodiments of the present disclosure. FIG. 3B is a schematic diagram of a structure of a reflective layer in a light-emitting chip according to some exemplary embodiments of the present disclosure.

Exemplarily, in some embodiments of the present disclosure, referring to FIG. 3A, the light-emitting chip 100 may further include a reflective layer 40 covering at least part of sidewalls 210 of the LED light-emitting unit 20. The reflective layer 40 includes a first reflective sub-layer 401, a second reflective sub-layer 402, and a third reflective sub-layer 403. The sidewalls 210 of the LED light-emitting unit includes a first sidewall 211, a second sidewall 212, and a third sidewall 213. For example, the first reflective sub-layer 401 covers at least part of the first sidewall 211. The second reflective sub-layer 402 covers at least part of the second sidewall 212. The third reflective sub-layer 403 covers at least part of the third sidewall 213. The first sidewall 211 includes a sidewall among the sidewalls 210 of the LED light-emitting unit on a side close to the first extraction electrode 208 and away from the second extraction electrode 209. The second sidewall 212 includes a sidewall among the sidewalls 210 of the LED light-emitting unit between the first extraction electrode 208 and the second extraction electrode 209. The third sidewall 213 includes a sidewall among the sidewalls 210 of the LED light-emitting unit on a side close to the second extraction electrode 209 and away from the first extraction electrode 208.

By adding the reflective layer on the side surface of the LED light-emitting unit, it is possible to effectively prevent light from leaking out from the side surface, so that the light output efficiency of the light output surface may be improved.

Exemplarily, in some embodiments of the present disclosure, referring to FIG. 3B, the reflective layer 40 includes a first passivation layer 410, a first metal reflective layer 420, and a second passivation layer 430. For example, a material of the first metal reflective layer may include Al or Ag. A material of each of the first passivation layer and the second passivation layer may include silicon oxide or silicon nitride, so as to prevent an electrical defect of the light-emitting chip caused by the first metal reflective layer.

FIG. 4 is a schematic diagram of a structure of a light-emitting chip according to some exemplary embodiments of the present disclosure.

Exemplarily, in some embodiments of the present disclosure, referring to FIG. 4, the light-emitting chip 100 further includes a first inorganic reflective layer 304 between the first semiconductor layer 303 and the first quantum well layer 302. For example, the first inorganic reflective layer 304 may include a stack of a GaAs layer and an AlAs layer. By adding the first inorganic reflective layer and using a Bragg reflection provided by the first inorganic reflective layer, at least part of the photoluminescence blue light in a lower layer may be reflected. Chromaticity of the light emitted by the light-emitting chip may be optimized, and the reflected part of the blue light may excite the first quantum well layer to emit the light of the second wavelength, such as red light, thereby improving the light efficiency of the light-emitting chip and enhancing the performance of the light-emitting chip.

FIG. 5 is a schematic diagram of a structure of a Mini-LED light-emitting chip according to some exemplary embodiments of the present disclosure.

Exemplarily, in some embodiments of the present disclosure, a Mini-LED light-emitting chip 500 is provided. Referring to FIG. 5, the Mini-LED light-emitting chip 500 may include: a second substrate 501; a second bonding layer 502 on the second substrate 501; and a light-emitting chip 100 on a side of the second bonding layer 502 away from the second substrate 501. The light-emitting chip 100 may include the light-emitting chip in any one of the above-mentioned embodiments. The second substrate 501 is on a light output side of the light-emitting chip 100.

After the light-emitting chip 100 is manufactured, processes such as substrate transfer, chip cutting and breaking may be further performed to reduce the size of the light-emitting chip, so as to obtain a plurality of individual small-sized Mini-LED light-emitting chips. For example, the light-emitting chip is transferred onto a glass or sapphire substrate, and then the substrate is thinned. The thickness of the substrate may be adjusted according to the size of the chip. The size of the Mini-LED light-emitting chip is in a range of 50 microns to 400 microns, and preferably, the size of the Mini-LED light-emitting chip is in a range of 80 microns to 300 microns. After the substrate transfer and light-emitting chip cutting are completed, substrate breaking may be further performed, for example, a laser invisible cutting technology may be used to cut the glass or sapphire substrate, and then a breaking machine is used for breaking, In this way, individual small-sized Mini-LED light-emitting chips may be obtained.

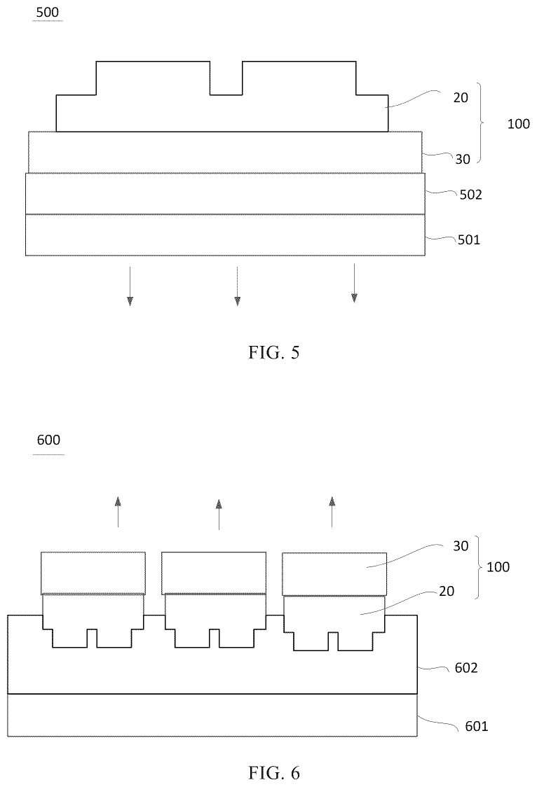

FIG. 6 is a schematic diagram of a structure of a light-emitting chip array according to some exemplary embodiments of the present disclosure.

Exemplarily, in some embodiments of the present disclosure, a light-emitting chip array 600 is provided, including: a first substrate 601; a third bonding layer 602 on the first substrate 601; and a plurality of light-emitting chips 100 arranged in an array on a side of the third bonding layer 602 away from the first substrate 601. The light-emitting chip 100 may include the light-emitting chip in any one of the above-mentioned embodiments. For example, after the light-emitting chip 100 is obtained, the light-emitting chip may be patterned. For example, the LED light-emitting unit 20 and the light conversion unit 30 may be patterned separately, so as to obtain an array of small-sized light-emitting chips. Arrays of light-emitting chips with different sizes may be obtained by controlling the patterning parameters. For example, an array of Micro-LED light-emitting chips with a size less than 100 microns may be obtained.

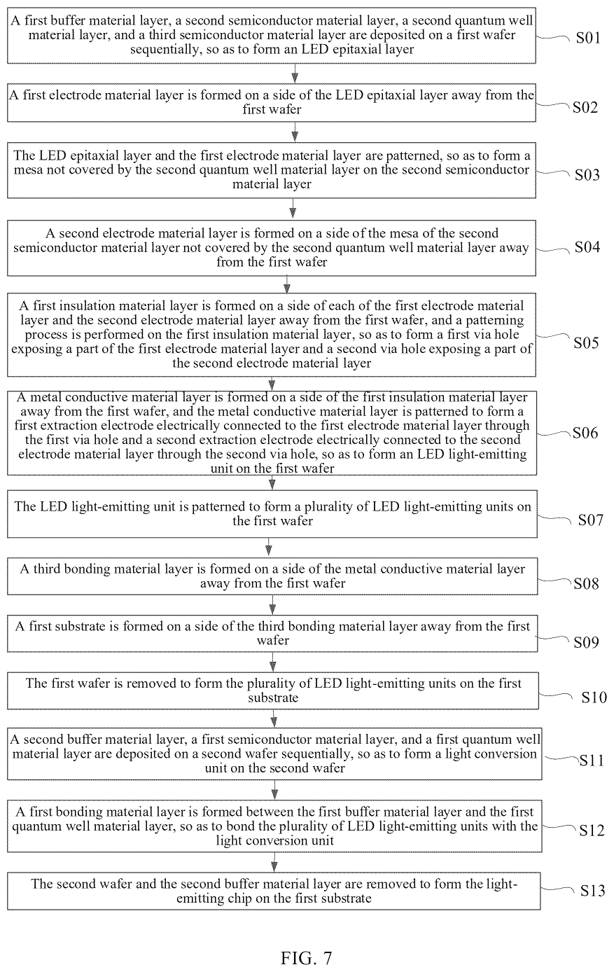

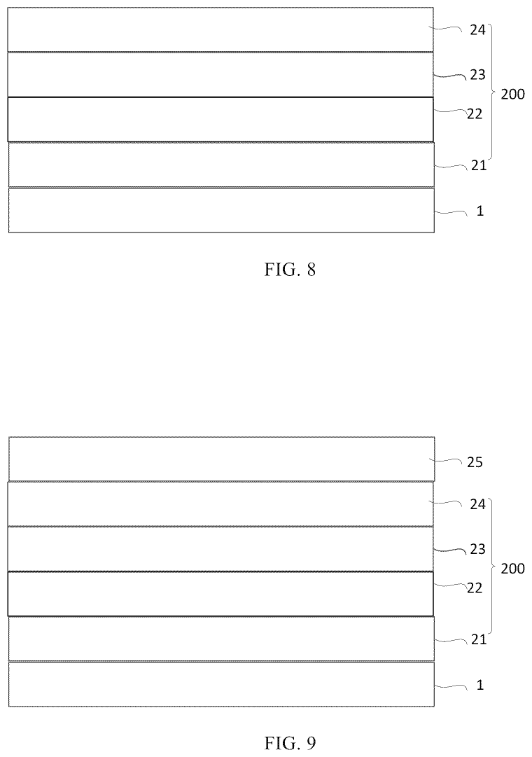

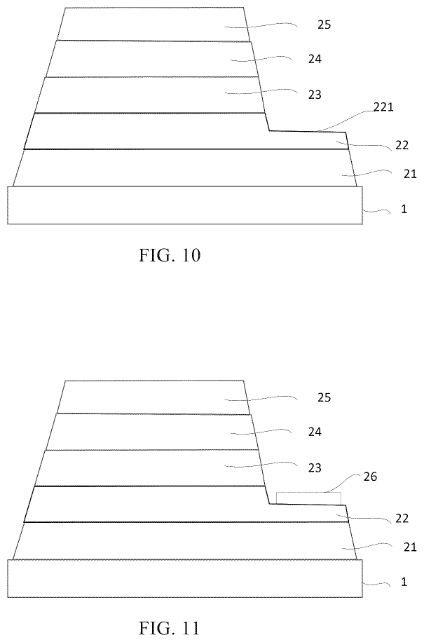

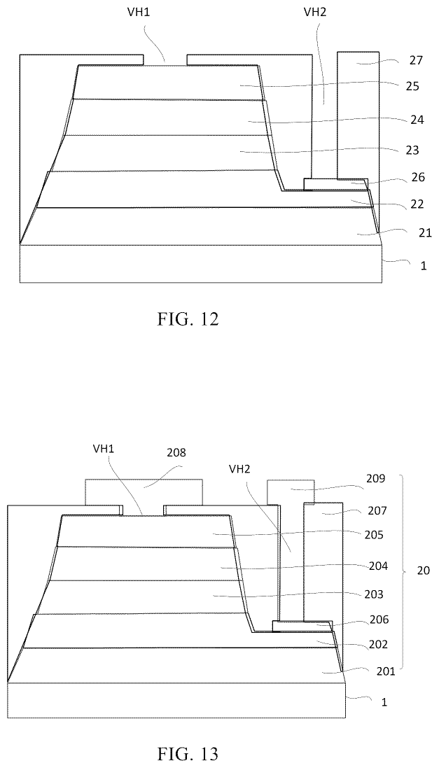

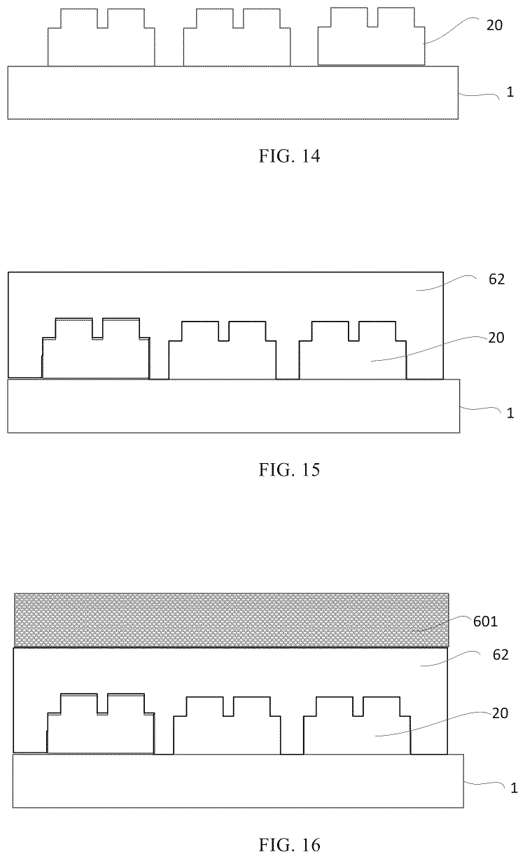

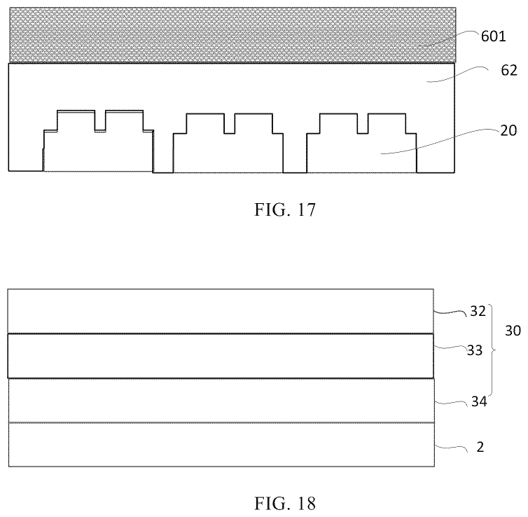

FIG. 7 is a flowchart of a method for manufacturing a light-emitting chip according to some exemplary embodiments of the present disclosure. FIG. 8 to FIG. 20 are respectively schematic diagrams showing a local structure of a light-emitting chip at different stages of the manufacturing process in FIG. 7.

Exemplarily, in some embodiments of the present disclosure, a method for manufacturing the light-emitting chip 100 is provided. For example, the method for manufacturing the light-emitting chip 100 includes steps S01 to S13.

In step S01, referring to FIG. 8, a first buffer material layer 21, a second semiconductor material layer 22, a second quantum well material layer 23 and a third semiconductor material layer 24 are sequentially deposited on a first wafer 1, so as to form an LED epitaxial layer 200.

In step S02, referring to FIG. 9, a first electrode material layer 25 is formed on a side of the LED epitaxial layer 200 away from the first wafer 1.

In step S03, referring to FIG. 10, the LED epitaxial layer 200 and the first electrode material layer 25 are patterned, so as to form a mesa 221 not covered by the second quantum well material layer 23 on the second semiconductor material layer 22.

In step S04, referring to FIG. 11, a second electrode material layer 26 is formed on a side of the mesa 221 of the second semiconductor material layer 22 away from the first wafer 1, where the mesa 221 is not covered by the second quantum well material layer 23.

In step S05, referring to FIG. 12, a first insulation material layer 27 is formed on a side of each of the first electrode material layer 25 and the second electrode material layer 26 away from the first wafer 1, and the first insulation material layer 27 is patterned, so as to form a first via hole VH1 exposing a part of the first electrode material layer 25 and a second via hole VH2 exposing a part of the second electrode material layer 26.

In step S06, referring to FIG. 13, a metal conductive material layer 28 is formed on a side of the first insulation material layer 27 away from the first wafer 1, and the metal conductive material layer 28 is patterned to form a first extraction electrode 208 electrically connected to the first electrode material layer through the first via hole VH1 and a second extraction electrode 209 electrically connected to the second electrode material layer through the second via hole VH2, so as to form an LED light-emitting unit 20 on the first wafer 1.

In step S07, referring to FIG. 14, the LED light-emitting unit 20 is patterned to form a plurality of LED light-emitting units 20 on the first wafer 1. For example, a side part of the LED light-emitting unit may be further deeply etched to ensure that GaN at a cutting path is etched off, which is beneficial for subsequent cutting of the LED light-emitting units.

In step S08, referring to FIG. 15, a third bonding material layer 62 is formed on a side of the metal conductive material layer 28 away from the first wafer 1. For example, in some embodiments, the third bonding material layer may employ a temporary bonding adhesive to facilitate the substrate transfer performed on the LED light-emitting chip in subsequent processes. The temporary bonding adhesive may be selected from a pyrolysis temporary bonding adhesive, a laser dissociation temporary bonding adhesive, a mechanical dissociation temporary bonding adhesive, or a chemical dissociation temporary bonding adhesive. In some other embodiments, the third bonding material layer may employ a permanent bonding adhesive.

In step S09, referring to FIG. 16, a first substrate 601 is formed on a side of the third bonding material layer 62 away from the first wafer 1. In some embodiments, the first substrate may include a temporary substrate to facilitate the substrate transfer performed on the LED light-emitting chip in subsequent processes. The temporary substrate may include sapphire, glass, quartz, or a silicon wafer. In some other embodiments, the first substrate may include a permanent substrate used as a support substrate for the light-emitting chip array, for example. a support substrate for the Micro-LED light-emitting chip array.

In step S10, referring to FIG. 17, the first wafer 1 is removed to form a plurality of LED light-emitting units 20 on the first substrate 601. For example, in a case that the first wafer is a sapphire substrate, a laser lift-off technology may be used for the removal. In a case that the first wafer is a silicon substrate, mechanical thinning and dry or wet etching may be used to remove the silicon substrate.

In step S11, referring to FIG. 18, a second buffer material layer 34, a first semiconductor material layer 33 and a first quantum well material layer 32 are sequentially deposited on a second wafer 2, so as to form a light conversion unit 30 on the second wafer 2.

In step S12, referring to FIG. 19, a first bonding material layer 31 is formed between the first buffer material layer 21 and the first quantum well material layer 32, so as to achieve a bonding between the plurality of LED light-emitting units 20 and the light conversion unit 30.

In step S13, referring to FIG. 20, the second wafer 2 and the second buffer material layer 34 are removed to form the light-emitting chip 100 on the first substrate 601.

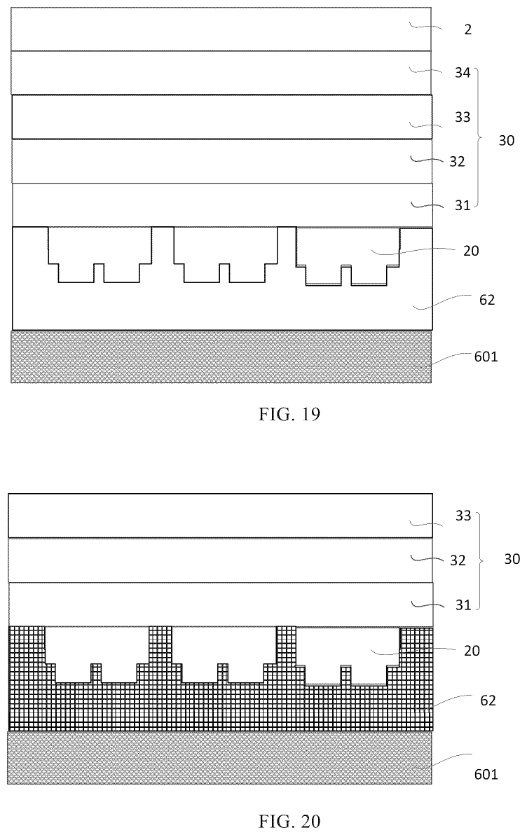

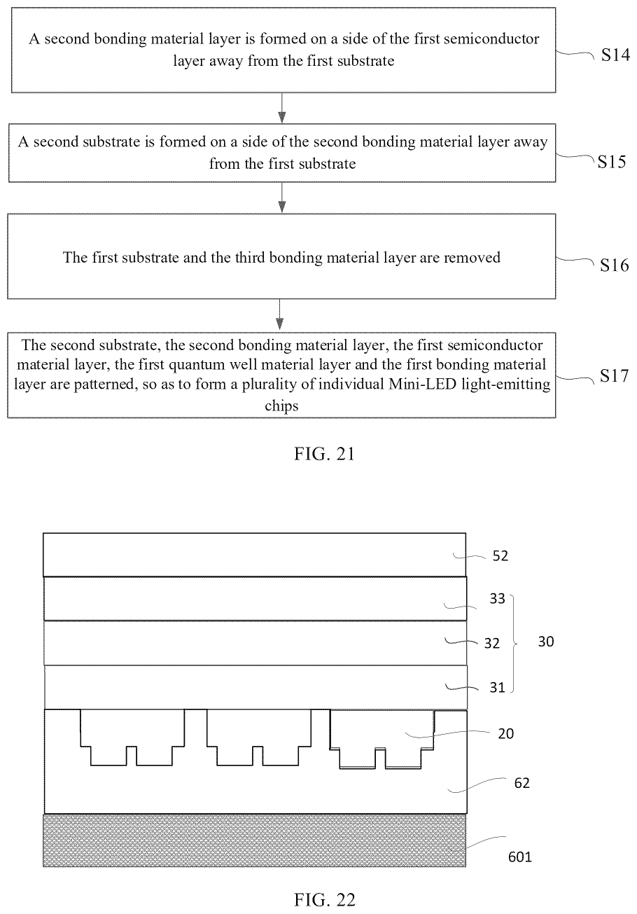

FIG. 21 is a flowchart of a method for manufacturing a Mini-LED light-emitting chip according to some exemplary embodiments of the present disclosure. FIG. 22 to FIG. 25 are respectively schematic diagrams showing a local structure of the Mini-LED light-emitting chip at different stages of the manufacturing process in FIG. 21.

Exemplarily, in some embodiments of the present disclosure, after the light-emitting chip 100 is formed on the first substrate 601, a further process may be performed to obtain a Mini-LED light-emitting chip.

Specifically, the method may further include: in step S07 of manufacturing the light-emitting chip 100 on the first substrate 601, adjusting the parameters of the patterning process, and patterning the LED light-emitting unit 20, so as to form a plurality of Mini-LED light-emitting units on the first wafer 1; and after the light-emitting chip 100 is formed on the first substrate 601, performing the following steps S14 to S17, where the light-emitting chip 100 includes the plurality of Mini-LED light-emitting units.

In step S14, referring to FIG. 22, a second bonding material layer 52 is formed on a side of the first semiconductor layer 303 away from the first substrate 601.

In step S15, referring to FIG. 23, a second substrate 501 is formed on a side of the second bonding material layer 52 away from the first substrate 601.

Exemplarily, in some embodiments, the formation of the second bonding material layer and the second substrate on the first semiconductor layer may be completed in the same process step or in different process steps.

In step S16, referring to FIG. 24, the first substrate 601 and the third bonding material layer 62 are removed.

In step S17, referring to FIG. 25, each of the second substrate 501, the second bonding material layer 52, the first semiconductor material layer 33, the first quantum well material layer 32 and the first bonding material layer 31 is patterned, so as to form the plurality of individual Mini-LED light-emitting chips 500. In some embodiments, before the second substrate is patterned, the second substrate may be thinned to facilitate a subsequent patterning process.

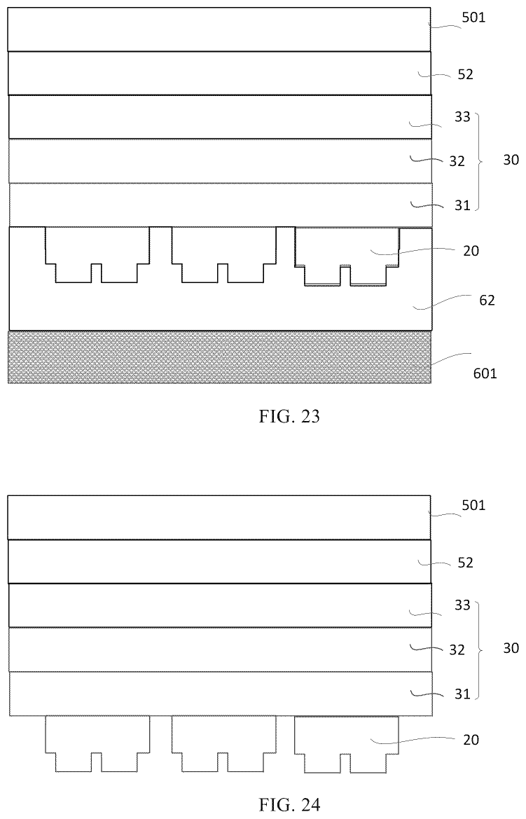

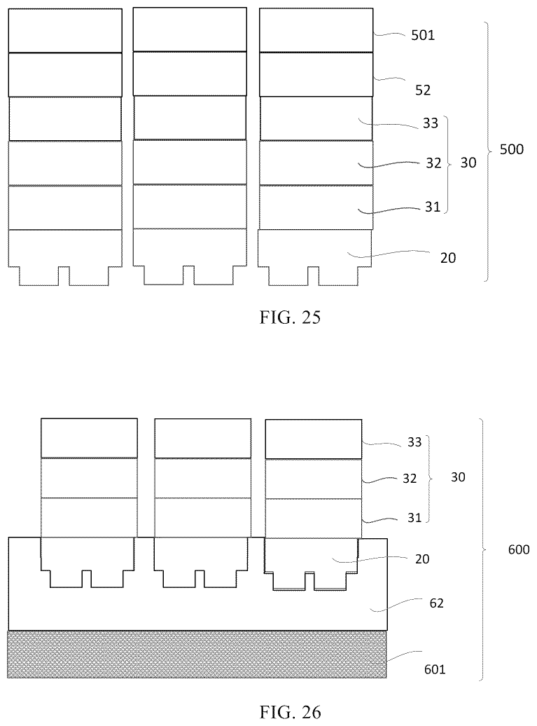

FIG. 26 is a schematic diagram of a structure of a light-emitting chip array according to some exemplary embodiments of the present disclosure.

Exemplarily, in some embodiments of the present disclosure, referring to FIG. 26, after the light-emitting chip 100 is formed on the first substrate 601, a further process may be performed to obtain a light-emitting chip array 600.

Exemplarily, each of the first semiconductor material layer 33, the first quantum well material layer 32 and the first bonding material layer 31 is patterned, so as to form a light-emitting chip array on the first substrate 601.

In some embodiments, by adjusting the size of the light-emitting chip in the light-emitting chip array, such as controlling the size of the light-emitting chip to be less than 100 microns, a Micro-LED light-emitting chip array may be obtained.

By combining the light conversion unit with the LED light-emitting unit, and using a high-efficiency blue or ultraviolet LED to excite the light conversion unit, light of other color may be formed. In this way, both an efficient output of light of various colors and the miniaturization of the LEDs may be achieved. For example, a high-efficiency red mini-LED light-emitting chip may be formed, or an array of high-efficiency red Micro-LED light-emitting chips may be formed, which is conducive to expanding application scenarios of the LED light-emitting chip.

With the development of LED miniaturization technology, LED light-emitting chips are widely used in display products, such as mini-LED display devices and Micro-LED display devices. A display substrate of a display device includes a large number of LED light-emitting chips. In a case that LED light-emitting chips are used to manufacture a display substrate, the LED light-emitting chips are usually used as light-emitting units in pixels. A color display substrate typically require pixel units of a plurality of colors, such as a red pixel unit, a green pixel unit, and a blue pixel unit. However, when the LED light-emitting chips are used as the light-emitting units of the display substrate, in the miniaturization of LEDs of different colors, degradation of efficiency of the LEDs are different from each other, which may easily cause non-uniformity of luminance and a color shift of a displayed image, thereby affecting the display quality. Especially in a Micro-LED display substrate, due to a low current, the efficiency of red light-emitting chips and the efficiency of green Micro-LED light-emitting chips decrease, resulting in a great decrease in luminance and a significant color shift of a displayed image, thereby seriously affecting the display effect of the display substrate.

Exemplarily, in some embodiments of the present disclosure, a high-resolution monochrome Micro-LED array is combined with the light color conversion technology to realize a high-resolution color display substrate. The high-resolution monochrome Micro-LED array may include a blue Micro-LED array or an ultraviolet Micro-LED array.

Exemplarily, the wavelength of light emitted by the blue Micro-LED may be in a range of 430 nm to 480 nm, and preferably, the wavelength of light emitted by the blue Micro-LED may be in a range of 450 nm to 465 nm. The wavelength of light emitted by the ultraviolet Micro-LED is less than or equal to 400 nm.

The high-resolution monochromatic Micro-LED array may be manufactured by bonding the entire epitaxial layer and then patterning it, so as to form a Micro-LED array. Alternatively, the LED chip may be patterned first to form a plurality of Micro-LED chips, and then aligning and bonding may be performed to form the Micro-LED array. For example, in the monochromatic Micro-LED array, a spacing between adjacent chips is less than or equal to 50 μm, and preferably, the spacing between adjacent chips is less than or equal to 10 μm.

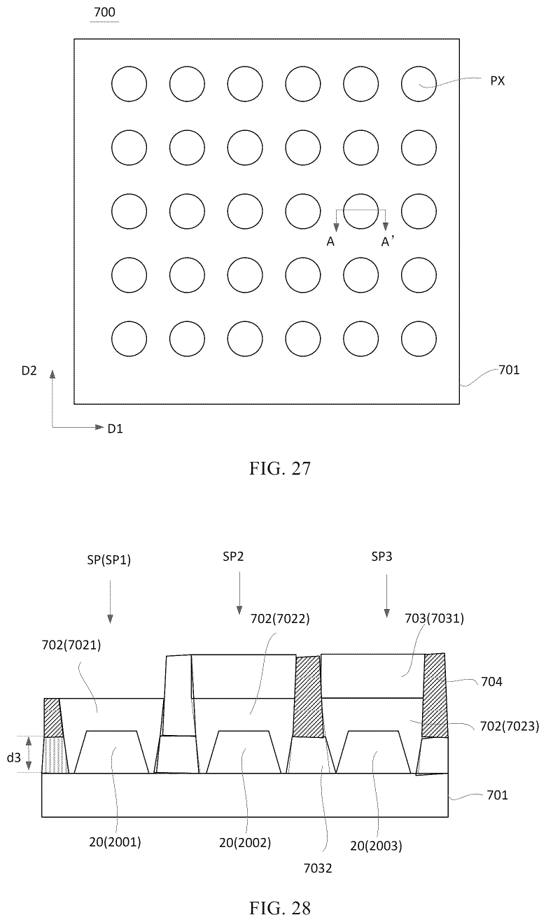

FIG. 27 is a schematic plan view of a display substrate according to some exemplary embodiments of the present disclosure. FIG. 28 is a schematic diagram of a local cross-section of the display substrate in FIG. 27 taken along line AA′ according to some exemplary embodiments of the present disclosure.

Exemplarily, in some embodiments of the present disclosure, a display substrate 700 is provided. Referring to FIG. 27 and FIG. 28, the display substrate 700 includes: a base substrate 701; and a plurality of pixel units PX on the base substrate 701. The plurality of pixel units PX are arranged in an array along a first direction D1 and a second direction D2, and the first direction D1 intersects with the second direction D2. At least one of the pixel units PX includes a plurality of sub-pixels SP, such as a first sub-pixel SP1, a second sub-pixel SP2, and a third sub-pixel SP3. Each of the first sub-pixel SP1, the second sub-pixel SP2 and the third sub-pixel SP3 includes an LED light-emitting unit 20 and a light guiding layer 702. The LED light-emitting unit 20 is configured to emit light of a first wavelength. The light guiding layers 702 of the sub-pixels SP may include a second light conversion layer 7022 on a light output side of an LED light-emitting unit 2002 of the second sub-pixel SP2, and the second light conversion layer 7022 is configured to convert the light of the first wavelength λ1 into light of a second wavelength λ. An orthographic projection of the LED light-emitting unit 2002 of the second sub-pixel SP2 on the base substrate 701 falls with an orthographic projection of the second light conversion layer 7022 on the base substrate 701.

The light guiding layers 702 of the sub-pixels SP may further include a third light conversion layer 7023 on a light output side of an LED light-emitting unit 2003 of the third sub-pixel SP3, and the third light conversion layer 7023 is configured to convert the light of the first wavelength λ into light of a third wavelength λ. An orthographic projection of the LED light-emitting unit 2003 of the third sub-pixel SP3 on the base substrate 701 falls within an orthographic projection of the third light conversion layer 7023 on the base substrate 701. The light of the first wavelength λ, a color of the light of the second wavelength λ is different from that of the light of the third wavelength λ. For example, the light of the first wavelength λ may include blue or ultraviolet light, the light of the second wavelength λ may include red light, and the light of the third wavelength λ may include green light. By designing the second and third light conversion layers, LED light-emitting units of a single type may be used to achieve sub-pixel units capable of emitting various colors, thereby achieving color display.

It should be noted that, the embodiments of the present disclosure schematically show that the pixel unit PX is circular in the drawings, however, in other embodiments, the pixel opening may also be rectangular, elliptical, square, triangular, etc. In addition, the light-emitting units of different colors corresponding to different pixel units may be arranged in various manners known in the art, and the embodiments of the present disclosure are not particularly limited.

Exemplarily, in some embodiments of the present disclosure, with continued reference to FIG. 28, the LED light-emitting unit may include an LED light-emitting unit that emits blue light. The second light conversion layer 7022 may include a red light quantum dot material; and/or, the third light conversion layer 7023 may include a green light quantum dot material.

By combining the blue light LED with red and green light quantum dots, sub-pixels including red, green, and blue sub-pixels may be formed using blue light LED light-emitting units of a single type, thereby achieving color display. By using the scheme of light color conversion, the process may be simplified and the process difficulty may be lowered. In addition, in the miniaturization of blue light LED light-emitting chips, the decrease of light efficiency is small, and variations of LED light-emitting chips of a single type are consistent, so that the color shift of the display substrate may be reduced and the luminance uniformity may be improved, thereby enhancing the display effect.

Exemplarily, in some embodiments of the present disclosure, referring to FIG. 28, in the case that the LED light-emitting unit is a LED light-emitting unit that emits blue light, the light guiding layers 702 of the sub-pixels SP may further include a first light guiding layer 7021 arranged on a light output side of an LED light-emitting unit 2001 of the first sub-pixel SP1. An orthographic projection of the LED light-emitting unit 2001 of the first sub-pixel SP1 on the base substrate 701 falls within an orthographic projection of the first light guiding layer 7021 on the base substrate 701. A material of the first light guiding layer 7021 includes scattering particles. By providing the scattering particles above the blue LED light-emitting unit, the light intensity and angle of the blue light emitted by the first sub-pixel SP1 may be adjusted, which may further improve the display effect of the display substrate.

Exemplarily, in some embodiments of the present disclosure, with continued reference to FIG. 28, the display substrate 700 may further include a second dielectric layer 703 on a side of the light guiding layers 702 away from the base substrate 701. The second dielectric layer 703 includes a main body portion 7031 and an isolation portion 7032, and the isolation portion 7032 is located in a gap between the light guiding layers 702 of adjacent sub-pixels SP. In the case that the LED light-emitting unit 20 is a LED light-emitting unit that emits blue light, an orthographic projection of the second dielectric layer 703 on the base substrate 701 does not overlap with the orthographic projection of the LED light-emitting unit 2001 of the first sub-pixel SP1 on the base substrate 701; and the orthographic projection of each of the LED light-emitting unit 2002 of the second sub-pixel SP2 and the LED light-emitting unit 2003 of the third sub-pixel SP3 on the base substrate 701 falls within an orthographic projection of the main body portion 7031 of the second dielectric layer 703 on the base substrate 701. For example, the second dielectric layer 703 may include a stacked structure of a SiO₂ layer and a TiO₂ layer; or the second dielectric layer may include a stacked structure of a SiO₂ layer and a NbO₂ layer; and/or, the second dielectric layer has a third thickness d3 in a direction perpendicular to the base substrate, and the third thickness d3 is less than or equal to 5 μm. Preferably, the third thickness d3 is less than or equal to 3 μm. By adjusting process parameters such as the material type and thickness of the second dielectric layer, a plurality of inorganic film layers may be used to selectively reflect and transmit light of different wavelengths. In this way, the second dielectric layer may be permitted to reflect blue light and transmit red and green light, thereby improving the light output efficiency of the second sub-pixel and the third sub-pixel.

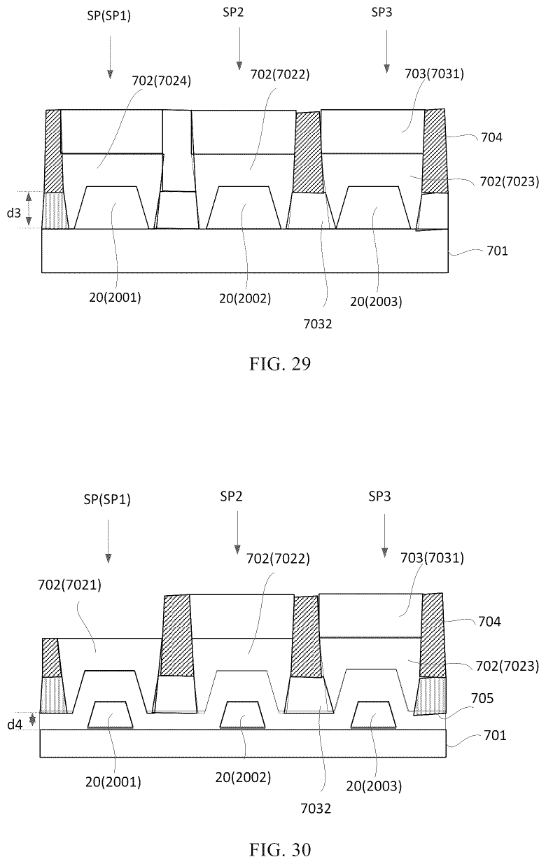

FIG. 29 is a schematic diagram of a local cross-section of the display substrate in FIG. 27 taken along line AA′ according to some other exemplary embodiments of the present disclosure.

Exemplarily, in some embodiments of the present disclosure, referring to FIG. 29, in the case that the LED light-emitting unit is a LED light-emitting unit that emits ultraviolet light, the light guiding layers 702 of the sub-pixels SP may further include a first light conversion layer 7024 arranged on the light output side of the LED light-emitting unit 2001 of the first sub-pixel SP1. The first light conversion layer 7024 is configured to convert the light of the first wavelength λ1 into light of a fourth wavelength λ. The color of the light of the first wavelength λ is different from that of the light of the fourth wavelength λ. For example, the light of the first wavelength is ultraviolet light, and the light of the fourth wavelength is blue light.

Exemplarily, the first light conversion layer 7024 may include a blue light quantum dot material; and the orthographic projection of the LED light-emitting unit 2001 of the first sub-pixel SP1 on the base substrate 701 falls within an orthographic projection of the first light conversion layer 7024 on the base substrate 701. By providing blue, red and green light quantum dots above the plurality of ultraviolet LED light-emitting units respectively, sub-pixels including red, green, and blue sub-pixels may be formed by using ultraviolet LED light-emitting units of a single type, thereby achieving color display. By using the scheme of light color conversion, the process may be simplified and the process difficulty may be lowered. In addition, in the miniaturization of ultraviolet LED light-emitting chips, the decrease of light efficiency is small and variations of LED light-emitting chips of a single type are consistent, so that the color shift of the display substrate may be reduced and the luminance uniformity of pixels may be improved, thereby enhancing the display effect.

Exemplarily, in some embodiments of the present disclosure, with continued reference to FIG. 29, the display substrate 700 further includes a second dielectric layer 703 arranged on a side of the light guiding layers 702 away from the base substrate 701. The second dielectric layer 703 includes a main body portion 7031 and an isolation portion 7032, and the isolation portion 7032 is located in a gap between the light guiding layers 702 of adjacent sub-pixels SP. The orthographic projection of each of the LED light-emitting unit 2001 of the first sub-pixel SP1, the LED light-emitting unit 2002 of the second sub-pixel SP2 and the LED light-emitting unit 2003 of the third sub-pixel SP3 on the base substrate 701 falls within an orthographic projection of the main body portion 7031 of the second dielectric layer 703 on the base substrate 701. The second dielectric layer 703 may include a stacked structure of a SiO₂ layer and a TiO₂ layer; or the second dielectric layer may include a stacked structure of a SiO₂ layer and a NbO₂ layer; and/or, the second dielectric layer has a third thickness d3 in the direction perpendicular to the base substrate, and the third thickness d3 is less than or equal to 5 μm. Preferably, the third thickness d3 is less than or equal to 3 μm. By adjusting the process parameters such as the material kind and thickness of the second dielectric layer, a plurality of inorganic film layers may be used to selectively reflect and transmit light of different wavelengths. In this way, the second dielectric layer may be permitted to reflect ultraviolet light and transmit blue, red and green light, thereby improving the light output efficiency of the first sub-pixel SP1, the second sub-pixel SP2 and the third sub-pixel SP3.

Exemplarily, in some embodiments of the present disclosure, referring to FIG. 28 and FIG. 29, the display substrate 700 further includes a black adhesive layer 704 on a side of a second dielectric layer 703 away from the base substrate 701. The black adhesive layer 704 is arranged between adjacent sub-pixels SP. The black adhesive layer 704 is configured to reflect at least part of light, which is emitted from one of the adjacent sub-pixels towards the other one of the adjacent sub-pixels. For example, a film pressing process may be used to press a black adhesive film onto sub-pixels. The thickness of the black adhesive layer in the black adhesive film is less than 20 μm. Preferably, the thickness of the black adhesive layer is less than 5 μm. Curing of the Black adhesive film is achieved with thermosetting or UV curable adhesive materials. Then, a chemical mechanical polishing method or a dry etching method may be used to remove a part of the black adhesive above the pixels, and the black adhesive in the gap between the sub-pixels is left. By providing a dam structure with large depth-to-width ratio, the problem of light crosstalk between different sub-pixels may be solved.

FIG. 30 is a schematic diagram of a local cross-section of the display substrate in FIG. 27 taken along line AA′ according to some other exemplary embodiments of the present disclosure. FIG. 31 is a schematic diagram of a local cross-section of the display substrate in FIG. 27 taken along line AA′ according to some other exemplary embodiments of the present disclosure.

Exemplarily, in some embodiments of the present disclosure, referring to FIG. 30 and FIG. 31, the display substrate 700 may further include a first dielectric layer 705 between the LED light-emitting units 20 and the light guiding layers 702. The first dielectric layer may include a stacked structure of a SiO₂ layer and a TiO₂ layer; or the first dielectric layer includes a stacked structure of a SiO₂ layer and a NbO₂ layer; and/or the first dielectric layer has a fourth thickness d4 in the direction perpendicular to the base substrate 701, and the fourth thickness d4 is less than or equal to 5 μm.

By adjusting the process parameters such as the material type and thickness of the first dielectric layer, a plurality of inorganic film layers may be used to selectively reflect and transmit light of different wavelengths. In this way, the first dielectric layer may be permitted to selectively reflect and transmit light emitted by the LED light-emitting units in the lower layer. For example, referring to FIG. 30, in the case that the light emitted by the lower LED light-emitting unit is blue light, the first dielectric layer may be designed to transmit blue light and reflect red and green light. Referring to FIG. 31, in the case that the light emitted by the lower LED light-emitting unit is ultraviolet light, the first dielectric layer may be designed to transmit ultraviolet light and reflect blue, red, and green light. By adding the first dielectric layer between the LED light-emitting units and the light guiding layers, the first dielectric layer may selectively reflect and transmit the light emitted by the LED light-emitting unit, so that the chromaticity of the light emitted by the pixel unit may be further optimized and the display effect of the display substrate may be improved.

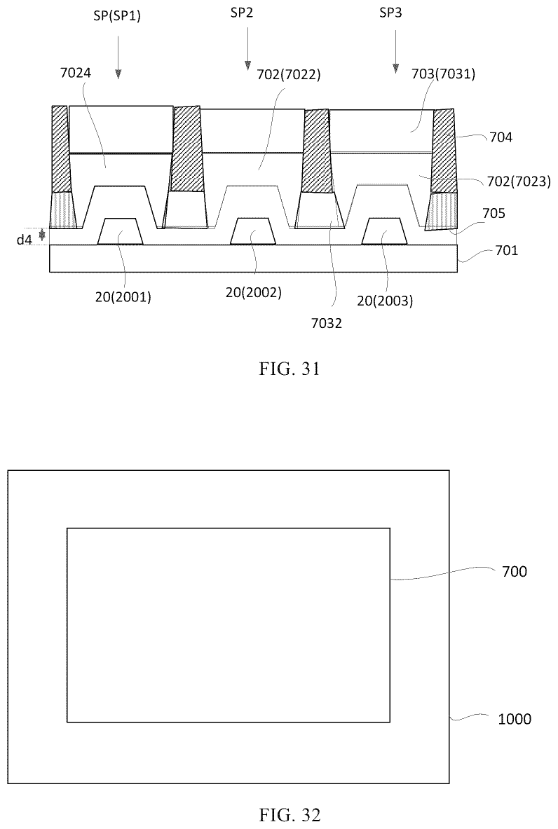

FIG. 32 is a schematic diagram of a structure of a display device according to some exemplary embodiments of the present disclosure.

Optionally, the embodiments of the present disclosure further provide a display device. Referring to FIG. 32, a display device 1000 may include the aforementioned display substrate 700. The display device may include but is not limited to: electronic papers, mobile phones, tablets, monitors, laptops, digital photo frames, navigation devices, and any other products or components with display functions. It should be understood that the display device has the same beneficial effects as the display substrate provided in the aforementioned embodiments.

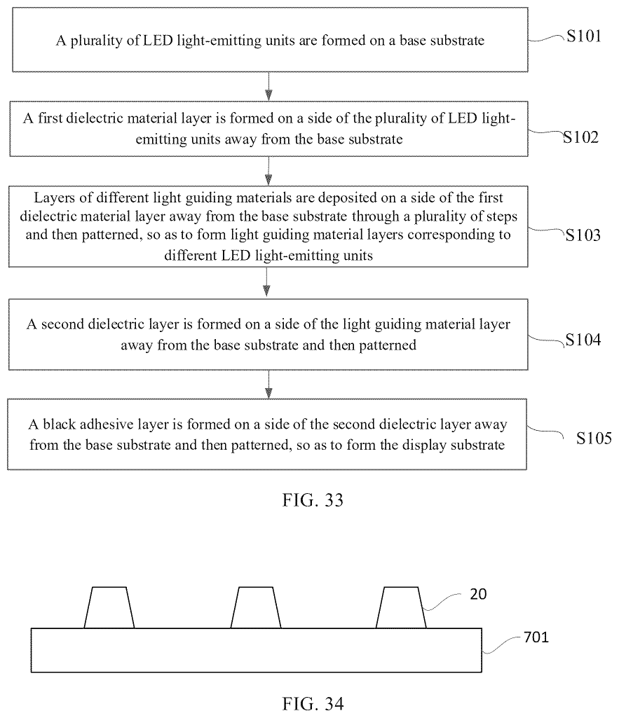

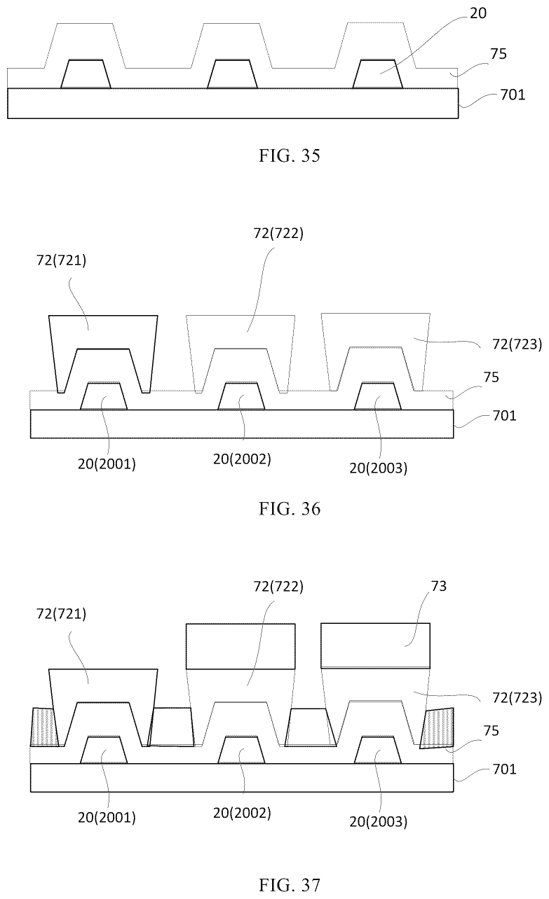

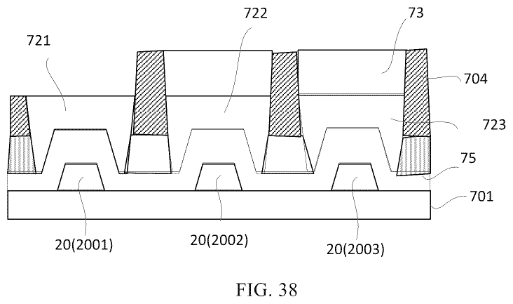

FIG. 33 is a flowchart of a method for manufacturing a display substrate according to some exemplary embodiments of the present disclosure. FIG. 34 to FIG. 38 are respectively schematic diagrams showing a local structure of the display substrate at different stages of the manufacturing process in FIG. 33.

Exemplarily, in some embodiments of the present disclosure, a method for manufacturing a display substrate includes steps S101 to S105.

In step S101, referring to FIG. 34, a plurality of LED light-emitting units 20 are formed on a base substrate 701.

In step S102, referring to FIG. 35, a first dielectric material layer 73 is formed on a side of the plurality of LED light-emitting units 20 away from the base substrate 701.

In step S103, referring to FIG. 36, layers of different light guiding materials are deposited on a side of the first dielectric material layer 75 away from the base substrate 701 through a plurality of steps respectively, and the layers of different light guiding materials is patterned, so as to form light guiding material layers 72 corresponding to different LED light-emitting units respectively. For example, a first light guiding material layer 721 may be deposited and then patterned to form a first light guiding film covering a LED light-emitting unit 2001; a second light conversion material layer 722 may be deposited and then patterned to form a second light conversion layer covering a LED light-emitting unit 2002; and a third light conversion material layer 723 may be deposited and then patterned to form a third light conversion layer covering a LED light-emitting unit 2003.

In step S104, referring to FIG. 37, a second dielectric layer 73 is formed on a side of the light guiding material layer 72 away from the base substrate 701, and the second dielectric layer 73 is patterned.

Exemplarily, in some embodiments of the present disclosure, in the case that the LED light-emitting unit emits blue light, during the patterning process of the second dielectric layer, an opening may be formed above the blue sub-pixel. For example, a yellow light process is used to provide a mask, and a dry etching method may be used to perform the patterning.

Exemplarily, in the case that the LED light-emitting unit emits ultraviolet light, the above patterning may be omitted during the patterning process of the second dielectric layer.

In step S105, referring to FIG. 38, a black adhesive layer 704 is formed on a side of the second dielectric layer 73 away from the base substrate 701, and the black adhesive layer 704 is patterned, so as to form the display substrate.

Although some embodiments of the present disclosure have been shown and illustrated, those ordinary skilled in the art will understand that changes may be made to these embodiments without departing from the principles and spirit of the present disclosure. The scope of the present disclosure is defined by the claims and their equivalents.

1. A light-emitting chip, comprising:
an LED light-emitting unit configured to emit light of a first wavelength; and
a light conversion unit on a light output side of the LED light-emitting unit, configured to convert the light of the first wavelength into light of a second wavelength, a color of the light of the first wavelength being different from a color of the light of the second wavelength,
wherein the light conversion unit comprises:
a first bonding layer on the light output side of the LED light-emitting unit;
a first quantum well layer on a side of the first bonding layer away from the LED light-emitting unit; and
a first semiconductor layer on a side of the first quantum well layer away from the LED light-emitting unit,
wherein the first quantum well layer is configured to emit the light of the second wavelength under an excitation of the light of the first wavelength.

2. The light-emitting chip according to claim 1, wherein the LED light-emitting unit comprises:
a first buffer layer on a side of the first bonding layer away from the first quantum well layer;
a second semiconductor layer on a side of the first buffer layer away from the first quantum well layer;
a second quantum well layer on a side of the second semiconductor layer away from the first quantum well layer;
a third semiconductor layer on a side of the second quantum well layer away from the first quantum well layer; and
a first electrode on a side of the third semiconductor layer away from the first quantum well layer.

3. The light-emitting chip according to claim 2, wherein the second semiconductor layer comprises a second electrode connection portion not covered by the second quantum well layer; and
the LED light-emitting unit further comprises: a second electrode on a side of the second electrode connection portion away from the first quantum well layer; and a first insulation layer on a side of each of the first electrode and the second electrode away from the first quantum well layer,
wherein the first insulation layer comprises a first via hole exposing at least a part of the first electrode and a second via hole exposing at least a part of the second electrode; and
wherein the LED light-emitting unit further comprises:
a first extraction electrode; and
a second extraction electrode,
wherein the first extraction electrode is electrically connected to the first electrode through the first via hole; and the second extraction electrode is electrically connected to the second electrode through the second via hole.

4. The light-emitting chip according to claim 2, wherein an orthographic projection of the second quantum well layer on the first bonding layer falls within an orthographic projection of the first quantum well layer on the first bonding layer.

5. The light-emitting chip according to claim 1, wherein:
a thickness of the first semiconductor layer is greater than or equal to 500 nm and less than or equal to 5 μm; and/or
a number of quantum well pairs in the first quantum well layer is greater than or equal to 10; and/or
a thickness of the first bonding layer is greater than or equal to 10 nm and less than or equal to 5 μm.

6. The light-emitting chip according to claim 1, wherein:
a material of the first semiconductor layer comprises AlGaInP; and/or
a material of the first quantum well layer comprises an AlGaInP quantum well; and/or
a material of the first bonding layer comprises at least one of SiO₂, benzocyclobutene, or SU8 negative photoresist.

7. The light-emitting chip according to claim 1, wherein:
the light of the first wavelength emitted by the LED light-emitting unit comprises light with a wavelength greater than or equal to 200 nm and less than or equal to 495 nm; and/or
the light of the second wavelength comprises light with a wavelength greater than or equal to 620 nm and less than or equal to 760 nm.

8. The light-emitting chip according to claim 1, further comprising:
a reflective layer covering at least part of sidewalls of the LED light-emitting unit,
wherein the reflective layer comprises a first reflective sub-layer, a second reflective sub-layer, and a third reflective sub-layer; the sidewalls of the LED light-emitting unit comprise a first sidewall, a second sidewall, and a third sidewall; the first reflective sub-layer covers at least a part of the first sidewall; the second reflective sub-layer covers at least a part of the second sidewall; and the third reflective sub-layer covers at least a part of the third sidewall,
wherein the first sidewall comprises a sidewall among the sidewalls of the LED light-emitting unit on a side close to the first extraction electrode and away from the second extraction electrode; the second sidewall comprises a sidewall among the sidewalls of the LED light-emitting unit between the first extraction electrode and the second extraction electrode; and the third sidewall comprises a sidewall among the sidewalls of the LED light-emitting unit on a side close to the second extraction electrode and away from the first extraction electrode;
wherein the reflective layer further comprises a first passivation layer, a first metal reflective layer, and a second passivation layer; and
wherein the light-emitting chip further comprises: a first inorganic reflective layer between the first semiconductor layer and the first quantum well layer, wherein the first inorganic reflective layer comprises a stack comprising a GaAs layer and an AlAs layer.

9-10. (canceled)

11. The light-emitting chip according to claim 2, wherein:
a material of the first electrode comprises ITO; and/or
a material of the second electrode comprises Ti or Cr; and/or
the first extraction electrode and the second extraction electrode are arranged in a same layer, and each of the first extraction electrode and the second extraction electrode comprises one of Ti, Al, Au, Sn, Ni or Pt, or an alloy of more than one selected from Ti, Al, Au, Sn, Ni or Pt, or a stack of more than one selected from Ti, Al, Au, Sn, Ni or Pt.

12. A Mini-LED light-emitting chip, comprising:
a second substrate;
a second bonding layer on the second substrate; and
a light-emitting chip on a side of the second bonding layer away from the second substrate,
wherein the light-emitting chip comprises the light-emitting chip according to claim 1; and
wherein the second substrate is arranged on a light output side of the light-emitting chip.

13. A light-emitting chip array, comprising:
a first substrate;
a third bonding layer on the first substrate; and
a plurality of light-emitting chips arranged in an array on a side of the third bonding layer away from the first substrate,
wherein the light-emitting chips comprise the light-emitting chip according to claim 1.

14. A method for manufacturing a light-emitting chip, comprising:
depositing a first buffer material layer, a second semiconductor material layer, a second quantum well material layer, and a third semiconductor material layer sequentially on a first wafer, so as to form an LED epitaxial layer;
forming a first electrode material layer on a side of the LED epitaxial layer away from the first wafer;
patterning the LED epitaxial layer and the first electrode material layer, so as to form a mesa not covered by the second quantum well material layer on the second semiconductor material layer;
forming a second electrode material layer on a side of the mesa of the second semiconductor material layer not covered by the second quantum well material layer away from the first wafer;
forming a first insulation material layer on a side of each of the first electrode material layer and the second electrode material layer away from the first wafer, and patterning the first insulation material layer, so as to form a first via hole exposing a part of the first electrode material layer and a second via hole exposing a part of the second electrode material layer;
forming a metal conductive material layer on a side of the first insulation material layer away from the first wafer, and patterning the metal conductive material layer to form a first extraction electrode electrically connected to the first electrode material layer through the first via hole and a second extraction electrode electrically connected to the second electrode material layer through the second via hole, so as to form an LED light-emitting unit on the first wafer;
patterning the LED light-emitting unit to form a plurality of LED light-emitting units on the first wafer;
forming a third bonding material layer on a side of the metal conductive material layer away from the first wafer;
forming a first substrate on a side of the third bonding material layer away from the first wafer;
removing the first wafer, so as to form the plurality of LED light-emitting units on the first substrate;
depositing a second buffer material layer, a first semiconductor material layer and a first quantum well material layer sequentially on a second wafer, so as to form a light conversion unit on the second wafer;
forming a first bonding material layer between the first buffer material layer and the first quantum well material layer, so as to bond the plurality of LED light-emitting units and the light conversion unit; and
removing the second wafer and the second buffer material layer, so as to form the light-emitting chip on the first substrate.

15. The method according to claim 14, wherein the patterning the LED light-emitting unit to form a plurality of LED light-emitting units on the first wafer comprises:
patterning the LED light-emitting unit to form a plurality of Mini-LED light-emitting units on the first wafer; and
wherein the method further comprises:
forming a second bonding material layer on a side of the first semiconductor layer away from the first substrate;
forming a second substrate on a side of the second bonding material layer away from the first substrate;
removing the first substrate and the third bonding material layer; and
patterning each of the second substrate, the second bonding material layer, the first semiconductor material layer, the first quantum well material layer, and the first bonding material layer, so as to form the plurality of individual Mini-LED light-emitting chips; or
wherein the patterning the LED light-emitting unit to form a plurality of LED light-emitting units on the first wafer comprises: performing the patterning process on the LED light-emitting unit to form a plurality of Micro-LED light-emitting units on the first wafer; and the method further comprises:
patterning each of the first semiconductor material layer, the first quantum well material layer, and the first bonding material layer, so as to form the plurality of Micro-LED light-emitting chips arranged in an array on the first substrate.

16. (canceled)

17. A display substrate, comprising:
a base substrate; and
a plurality of pixel units on the base substrate, wherein at least one of the plurality of pixel units comprises a first sub-pixel, a second sub-pixel, and a third sub-pixel,
wherein each of the first sub-pixel, the second sub-pixel and the third sub-pixel comprises an LED light-emitting unit and a light guiding layer, and the LED light-emitting unit is configured to emit light of a first wavelength,
wherein the light guiding layers of the sub-pixels comprise a second light conversion layer on a light output side of the LED light-emitting unit of the second sub-pixel, and the second light conversion layer is configured to convert the light of the first wavelength into a light of a second wavelength,
wherein an orthographic projection of the LED light-emitting unit of the second sub-pixel on the base substrate falls with an orthographic projection of the second light conversion layer on the base substrate;
wherein the light guiding layers of the sub-pixels further comprises a third light conversion layer on a light output side of the LED light-emitting unit of the third sub-pixel, and the third light conversion layer is configured to convert the light of the first wavelength into light of a third wavelength,
wherein an orthographic projection of the LED light-emitting unit of the third sub-pixel on the base substrate falls within an orthographic projection of the third light conversion layer on the base substrate, and
wherein colors of the light with the first wavelength, the light with the second wavelength and the light with the third wavelength are different from each other.

18. The display substrate according to claim 17, wherein:
the second light conversion layer comprises a red light quantum dot material; and/or
the third light conversion layer comprises a green light quantum dot material.

19. The display substrate according to claim 18, wherein the light guiding layers of the sub-pixels further comprises a first light guiding layer on a light output side of the LED light-emitting unit of the first sub-pixel,
wherein an orthographic projection of the LED light-emitting unit of the first sub-pixel on the base substrate falls within an orthographic projection of the first light guiding layer on the base substrate; and
wherein a material of the first light guiding layer comprises scattering particles;
wherein the display substrate further comprises:
a second dielectric layer on a side of the light guiding layers away from the base substrate,
wherein the second dielectric layer comprises a main body portion and an isolation portion, and the isolation portion is in a gap between light guiding layers of adjacent sub-pixels;
wherein an orthographic projection of the second dielectric layer on the base substrate does not overlap with the orthographic projection of the LED light-emitting unit of the first sub-pixel on the base substrate; and
wherein an orthographic projection of each of the LED light-emitting unit of the second sub-pixel and the LED light-emitting unit of the third sub-pixel on the base substrate falls within an orthographic projection of the main body portion of the second dielectric layer on the base substrate.

20. The display substrate according to claim 18, wherein the light guiding layers of the sub-pixels further comprises a first light conversion layer on a light output side of the LED light-emitting unit of the first sub-pixel, the first light conversion layer is configured to convert the light of the first wavelength into light of a fourth wavelength, and a color of the light of the first wavelength is different from a color of the light of the fourth wavelength,
wherein the first light conversion layer comprises a blue light quantum dot material;
wherein an orthographic projection of the LED light-emitting unit of the first sub-pixel on the base substrate falls within an orthographic projection of the first light conversion layer on the base substrate;
wherein the display substrate further comprises: a second dielectric layer on a side of the light guiding layers away from the base substrate;
wherein the second dielectric layer comprises a main body portion and an isolation portion, and the isolation portion is in a gap between light guiding layers of adjacent sub-pixels;
wherein an orthographic projection of each of the LED light-emitting unit of the first sub-pixel, the LED light-emitting unit of the second sub-pixel and the LED light-emitting unit of the third sub-pixel on the base substrate falls within an orthographic projection of the main body portion of the second dielectric layer on the base substrate; and
wherein:
the second dielectric layer comprises a stacked structure of a SiO2 layer and a TiO2 layer; or the second dielectric layer comprises a stacked structure of a SiO2 layer and a NbO2 layer; and/or
the second dielectric layer has a third thickness in a direction perpendicular to the base substrate, and the third thickness is less than or equal to 5 μm.

21-23. (canceled)

24. The display substrate according to claim 17, further comprising:
a first dielectric layer between the LED light-emitting units and the light guiding layers,
wherein:
the first dielectric layer comprises a stack of a SiO₂ layer and a TiO₂ layer; or the first dielectric layer comprises a stacked structure of a SiO₂ layer and a NbO₂ layer; and/or,
the first dielectric layer has a fourth thickness in a direction perpendicular to the base substrate, and the fourth thickness is less than or equal to 5 μm; and
wherein the display substrate further comprises: a black adhesive layer between adjacent sub-pixels, the black adhesive layer is located on a side of a second dielectric layer away from the base substrate and is configured to reflect at least part of light, which is emitted from one of the adjacent sub-pixels towards the other one of the adjacent sub-pixels.

25. (canceled)

26. A display device, comprising the display substrate according to claim 17.

27. A method for manufacturing the display substrate according to claim 17, comprising:
forming the plurality of LED light-emitting units on a base substrate;
forming a first dielectric material layer on a side of the plurality of LED light-emitting units away from the base substrate;
depositing layers of different light guiding materials on a side of the first dielectric material layer away from the base substrate through a plurality of steps respectively, and patterning the layers of different light guiding materials, so as to form light guiding material layers corresponding to different LED light-emitting units respectively;
forming a second dielectric layer on a side of the light guiding material layers away from the base substrate, and patterning the second dielectric layer; and
forming a black adhesive layer on a side of the second dielectric layer away from the base substrate and patterning the black adhesive layer, so as to form the display substrate.
